(19) United States
(12) Patent Application Publication
(10) Pub. No.: US 2024/0427083 A1
(43) Pub. Date: Dec. 26, 2024

(54) SYSTEMS AND METHODS FOR TRIMMING PHOTONIC INTEGRATED CIRCUITS

(71) Applicant: PHOTONIC INC., Coquitlam (CA)

(72) Inventor: Mohsen KESHAVARZ AKHLAGHI, North Vancouver (CA)

(21) Appl. No.: 18/824,656

(22) Filed: Sep. 4, 2024

Related U.S. Application Data
(63) Continuation-in-part of application No. PCT/CA2023/050342, filed on Mar. 16, 2023.
(60) Provisional application No. 63/320,734, filed on Mar. 17, 2022.

(51) Int. Cl. G02B 6/13

(52) U.S. Cl. CPC G02B 6/13

(57) ABSTRACT

A system for trimming a photonic chip comprises a fabrication unit and a system controller communicatively coupled to the fabrication unit. The system controller is configured to cause the fabrication unit to fabricate the photonic chip in an offset state. The system controller is further configured to generate one or more trim patterns based on an optical performance of the photonic chip and a first target optical performance of the photonic chip. The system controller is further configured to create a patterned resist on the photonic chip based on the one or more trim patterns and trim the photonic chip by exposure to a plasma of reactive gas, wherein the reactive gas is one of oxygen or nitrogen.

### CROSS-REFERENCE TO RELATED APPLICATIONS

This application is a continuation-in-part of PCT application No. PCT/CA2023/050342 filed 16 Mar. 2023 and entitled SYSTEMS AND METHODS FOR TRIMMING PHOTONIC INTEGRATED CIRCUITS, which claims the benefit under 35 U.S.C. § 119 of U.S. application No. 63/320,734 filed 17 Mar. 2022 and entitled SYSTEMS AND METHODS FOR TRIMMING PHOTONIC INTEGRATED CIRCUITS. Each of PCT application No. PCT/CA2023/050342 and U.S. application No. 63/320,734 is hereby incorporated herein by reference for all purposes.

### FIELD

The present disclosure generally relates to fabricating photonic integrated circuits, and particularly to systems and methods for trimming photonic integrated circuits.

### BACKGROUND

Silicon, a semiconductor, is the backbone material of modern integrated circuits (also referred to as chips). A typical chip manufacturing process starts with preparing silicon wafers and defining micro-devices and nano-devices within the wafer using lithography, implantation, and deposition techniques. Advances in the field have demanded ever increasing control over the specifications of such fabrication schemes. As a result, silicon processing has become the most available process and silicon the most known material for realization of such micro-devices and nano-devices. A property of silicon is that it can be oxidized into silicon dioxide. Silicon dioxide is an insulator. A thin film of silicon on an insulator (SOI) is widely used as an alternative wafer substrate over which micro-devices and nano-devices can be built. Compared to micro-devices and nano-devices realized on conventional silicon wafers, devices realized on SOI wafers offer advantages such as reduced parasitic capacitance, lower power consumption, and shorter gate delay.

Silicon and silicon dioxide are transparent materials at infrared wavelengths. Because the refractive index of silicon is higher than that of silicon dioxide, patterning a silicon slab using conventional lithographic techniques yields structures that can accept and guide infrared optical signals over a surface, in the same manner as metallic wires are used in transmitting electrical signals. Such optical integrated circuits define the field of silicon photonics. Silicon photonic chips can benefit from manufacturing techniques compatible with electronic chip manufacturing. They can provide optical functionalities useful for a variety of applications including, for example, telecommunication transceiver modules, optical computers, and optical bio sensing.

A silicon photonic chip may contain many active and passive elements. These include waveguides, grating couplers, edge couplers, directional couplers, ring resonators, photonic crystals, and optical detectors, all of which can be monolithically fabricated. A property of silicon is in its high index contrast in comparison to other readily available materials, such as silicon dioxide. This property enables a silicon structure, when surrounded by lower index materials, to act as the optical core material. Also, the high index contrast facilitates making the elements small and enables dense integration of complex optical circuitry.

### SUMMARY

The present technology provides methods and systems for fabricating photonic chips and/or trimming photonic devices as well as partially processed substrates for fabrication of photonic chips.

According to a first aspect there is provided a method of trimming an integrated photonic device including: fabricating a photonic device; optically measuring the photonic device generating optical measurements; determining trim patterns with use of the optical measurements; creating a patterned resist on the photonic device with use of the determined trim patterns; and trimming the photonic device with a plasma process, converting a thickness of a core material of the photonic device exposed by openings in the patterned resist into a different material which may be retained in the photonic device after final fabrication.

According to another aspect there is provided a method of trimming an integrated photonic device. The method includes generating one or more trim patterns at least based on optical measurement of the photonic device, creating a patterned resist on the photonic device based on the one or more trim patterns, and trimming the photonic device to adjust a performance metric of the photonic device.

According to another aspect there is provided a method of trimming an integrated photonic device. The method comprises optically measuring the photonic device; generating one or more trim patterns based on at least the optical measurements; creating a patterned resist on the photonic device based on the one or more trim patterns; and trimming the photonic device to adjust a performance metric of the photonic device. The trimming comprises exposing the photonic device to a plasma comprising a reactive gas via one or more openings in the patterned resist.

According to another aspect there is provided methods having any new and inventive steps, acts, combination of steps and/or acts or sub-combination of steps and/or acts as described herein.

According to another aspect there is provided a system for trimming a photonic chip. The system includes a fabrication unit and a system controller communicatively coupled to the fabrication unit. The system controller is configured to cause the fabrication unit to fabricate the photonic chip in an offset state. The system controller is further configured to generate one or more trim patterns based on the optical performance of the photonic chip and a first target optical performance of the photonic chip. The system controller is further configured to create a patterned resist on the photonic chip based on the one or more trim patterns and trim the photonic chip by exposure to a plasma of reactive gas, wherein the reactive gas is one of oxygen or nitrogen.

According to another aspect there is provided a system for trimming one or more photonic devices of a photonic chip. The system comprises a system controller, a measurement unit; and a plasma chamber. The system controller is configured to: acquire from the measurement unit optical measurements of optical characteristics of one or more photonic devices on a photonic chip and generate a respective trim pattern for the one or more photonic devices based on the optical measurements. The system controller is further configured to control a fabrication unit to create a patterned resist on the photonic chip based on the trim patterns. One or more photonic devices of the photonic chip may be trimmed by exposing the photonic chip with patterned resist to a plasma in the plasma chamber, the plasma comprising a reactive gas selected from oxygen and nitrogen.

According to another aspect there is provided a system for trimming one or more photonic devices of a photonic chip. The system comprises: a fabrication unit; and a system controller communicatively coupled to the fabrication unit. The system controller is configured to: cause the fabrication unit to fabricate the photonic chip such that the one or more photonic devices is in an offset state; generate one or more trim patterns based on an optical performance of the one or more photonic devices and a first target optical performance for the one or more photonic device of the photonic chip; create a patterned resist on the photonic chip based on the one or more trim patterns; and trim the one or more photonic devices of the photonic chip by exposure to a plasma comprising a reactive gas, wherein the reactive gas is one of oxygen or nitrogen.

According to another aspect there is provided apparatuses having any new and inventive feature, combination of features, or sub-combination of features as described herein.

In some embodiments the photonic device comprises a core and the trimming comprises converting a portion of the core from one material into another different material.

In some embodiments, the photonic device comprises a silicon core.

In some embodiments, the core material comprises silicon.

In some embodiments, the plasma process comprises an oxygen plasma process and the different material is silicon dioxide.

In some embodiments, the plasma process comprises a nitrogen plasma process and the different material is silicon nitride.

In some embodiments the portion of the core is a layer having a thickness of more than 2 nm. In some embodiments the portion of the core is a layer having a thickness in the range of 2 nm to 10 nm.

In some embodiments the core is a silicon core.

In some embodiments the trimming comprises converting a portion of the core into silicon nitride.

In some embodiments the trimming comprises converting the portion of the core into silicon dioxide.

In some embodiments generating the one or more trim patterns is further based on a target optical performance for the photonic device.

In some embodiments methods include fabricating the photonic device in an offset state in which a value of the performance metric in the offset state is different from a predefined optimal value and the trimming causes the value of the performance metric to approach the predefined optimal value.

In some embodiments methods comprise fabricating the photonic device in an offset state in which a value of the performance metric in the offset state is less than a predefined optimal value.

In some embodiments methods comprise fabricating the photonic device in an offset state in which a value of the performance metric in the offset state is greater than a predefined optimal value.

In some embodiments methods comprise generating one or more process parameters based on the optical measurements and performing the trimming using the one or more process parameters. In some embodiments the process parameters comprise a plasma chamber pressure and/or an RF power applied to the plasma chamber and the process parameters are selected to cause plasma penetration into the photonic device to a depth in the range of 2 nm to 10 nm.

In some embodiments optically measuring the photonic device comprises coating the photonic device with a temporary material; optically measuring the coated photonic device; and removing the temporary material prior to creating the patterned resist. In some embodiments the temporary material has an index of refraction substantially the same as a material to be added to the photonic device in a later step.

In some embodiments methods comprise iteratively repeating the steps of: optically measuring the photonic device; generating one or more trim patterns based on at least the optical measurements; creating a patterned resist on the photonic device based on the one or more trim patterns; and trimming the photonic device to adjust a performance metric of the photonic device; and thereby causing a value of the performance metric of the photonic device to progressively approach an optimum or target value for the performance metric of the photonic device.

In some embodiments the photonic device is one of a plurality of photonic devices fabricated on a common substrate, the method comprises performing the steps of the method for each of the plurality of photonic devices, and at least a step of trimming the photonic device to adjust a performance metric of the photonic device is performed simultaneously for the plurality of photonic devices.

In some embodiments the photonic device comprises an optical resonator, an optical filter, or an optical waveguide.

In some embodiments the photonic device is a photonic crystal device.

In some embodiments the photonic device comprises an optical resonator and the performance metric of the photonic device comprises a resonant wavelength or resonant frequency or Q-factor of the optical resonator.

In some embodiments the plasma comprises a mixture of the reactive gas with an inert gas. In some embodiments the inert gas is argon.

In some embodiments the plasma comprises a plasma of a plasma mixture comprising 15-50% oxygen and 50-85% argon.

In some embodiments the first target optical performance is a predefined optimal optical performance of the one or more photonic device in which a performance metric has a predefined optimal value.

In some embodiments the offset state is a state in which a value of the performance metric in the offset state is different from the predefined optimal value and the trimming causes the value of the performance metric to approach the predefined optimal value.

In some embodiments optical performance of the one or more photonic device and the first target optical performance of the one or more photonic device are measured by a performance metric and a value of the performance metric in the in the offset state is less than a predefined optimal value for the performance metric.

In some embodiments the optical performance of the one or more photonic device and the first target optical performance of the one or more photonic device are measured by a performance metric and a value of the performance metric in the offset state is greater than a predefined optimal value for the performance metric.

In some embodiments systems comprise a test unit communicatively coupled to the fabrication unit and the system controller, wherein the test unit is configured to perform an optical characterization of one or more of the one or more photonic device on the photonic chip to thereby determine the optical performance of the one or more of the one or more photonic device.

In some embodiments the photonic chip comprises a core and the plasma comprising the reactive gas is effective to convert a portion of the core from one material into another material.

In some embodiments the photonic chip comprises a core and the plasma comprising the reactive gas is effective to convert a portion of the core from one material into another material.

In some embodiments t the system controller is configured to generate one or more process parameters based on optical measurements made on the photonic chip and to control the trimming using the one or more process parameters.

In some embodiments systems comprise a plasma chamber and the process parameters comprise a plasma chamber pressure and/or an RF power applied to the plasma chamber and the process parameters are selected to cause plasma penetration into the photonic chip to a depth in the range of 2 nm to 10 nm.

In some embodiments the one or more photonic device includes a plurality of photonic devices fabricated on a common substrate, and the system controller is configured to perform, for each of the plurality of photonic devices, the steps of: generate one or more trim patterns for the photonic device based on an optical performance of the photonic device and a first target optical performance for the photonic device; create a patterned resist on the photonic chip based on the one or more trim patterns; and trim the photonic device by exposure to a plasma comprising a reactive gas. The reactive gas is one of oxygen or nitrogen. At least the step of trimming the photonic device is performed simultaneously for the plurality of photonic devices.

In some embodiments the system controller is further configured to generate a photonic chip design according to which the photonic chip is fabricated.

In some embodiments, the determination of the trim patterns is performed with use of a target optical performance for the photonic device.

In some embodiments, the target optical performance is a final target optical performance for the photonic device or corresponds to a target optical performance closer to a final target optical performance than an optical performance indicated by the optical measurements.

In some embodiments, the plasma process is performed with a saturation level for a duration of time such that the trimming of the photonic device changes the optical performance of the photonic device to match a predetermined target optical performance.

In some embodiments, the determination of the trim patterns further comprises determining process parameters for the equipment used to perform the plasma process with the saturation level.

In some embodiments, fabricating the photonic device is performed according to a design determined to produce a statistical distribution of photonic devices in an initial state having various optical performance levels around an initial target optical performance which are correctable by the trimming.

In some embodiments, optically measuring the photonic device includes: coating the photonic device with a temporary material to simulate a final performance of the photonic device after final fabrication; and optically measuring the coated photonic device generating the optical measurements. The temporary material may be removed prior to creating the patterned resist.

In some embodiments, the temporary material has an index of refraction substantially the same as a material to be added to the photonic device after trimming and retained after final fabrication.

In some embodiments, the plasma process utilizes oxygen plasma or nitrogen plasma and excludes additional etching agents.

Some embodiments further provide for, after the trimming the photonic device, optically measuring the photonic device generating further optical measurements, determining with use of the further optical measurements that the photonic device is acceptable for an offset state; determining further trim patterns with use of the further optical measurements; creating a further patterned resist on the photonic device with use of the determined further trim patterns; and further trimming the photonic device with a further plasma process, converting a further thickness of the core material of the photonic device exposed by openings in the further patterned resist into the different material which is retained in the photonic device after final fabrication.

In some embodiments, determining the trim patterns is performed with use of a first target optical performance for the photonic device, in which the determining further trim patterns is performed with use of a second target optical performance, and in which the second target optical performance is closer to a final target optical performance than the first target optical performance.

In some embodiments, the plasma process is performed with a first process setting such that when used with the patterned resist the trimming of the photonic device changes the optical performance of the photonic device by a first predetermined amount, and in which the further plasma process is performed with a first saturation level for a first duration of time such that when used with the further patterned resist the further trimming of the photonic device changes the optical performance of the photonic device by a second predetermined amount.

In some embodiments, the first predetermined amount is greater than the second predetermined amount.

Some embodiments further provide for iteratively performing, a number times, process steps including: after a previous trimming the photonic device, optically measuring the photonic device generating further optical measurements, determining with use of the further optical measurements that the photonic device is not acceptable determining further trim patterns with use of the further optical measurements; creating a further patterned resist on the photonic device with use of the determined further trim patterns; and further trimming the photonic device with a further plasma process, converting a further thickness of the core material of the photonic device exposed by openings in the further patterned resist into the different material which may be retained in the photonic device after final fabrication.

Some embodiments further provide for, after iteratively performing, the number of times, the process steps: optically measuring the photonic device generating final optical measurements; and determining with use of the final optical measurements that the photonic device is acceptable.

In some embodiments, the plasma process employs a plasma chamber pressure less than that used in a descum process.

In some embodiments, the plasma process employs a plasma chamber pressure less than that used in a descum process and an RF power less than that of an etching process.

The foregoing and additional aspects and embodiments of the present disclosure will be apparent to those of ordinary skill in the art in view of the detailed description of various embodiments and/or aspects, which is made with reference to the drawings, a brief description of which is provided next.

Further aspects and example embodiments are illustrated in the accompanying drawings and/or described in the following description.

It is emphasized that the invention relates to all combinations of the above features, even if these are recited in different claims.

### BRIEF DESCRIPTION OF THE DRAWINGS

The foregoing and other advantages of the disclosure will become apparent upon reading the following detailed description and upon reference to the drawings which illustrate non-limiting example embodiments of the invention.

FIG. 1 is a block diagram of a system for manufacturing a photonic chip according to an exemplary embodiment of the invention.

FIG. 2 illustrates a statistical distribution of devices on a photonic chip according to a performance metric.

FIG. 3 is a flowchart describing a method of trimming a photonic chip according to an exemplary embodiment of the invention.

FIG. 4 is a plan view of a nanobeam cavity device showing example application of the method of trimming of FIG. 3.

FIG. 5 illustrates a simulated trimming curve of the resonance wavelength for the nanobeam cavity device of FIG. 4 versus parameter X, that defines a degree of trimming applied to the nanobeam cavity device.

FIG. 6 is a plan view of a micro-ring device showing an example application of the method of trimming of FIG. 3.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive sense.

The foregoing summary, as well as the following detailed description of certain examples will be better understood when read in conjunction with the appended drawings.

The high index contrast between silicon and other materials such as silicon dioxide imposes a few practical challenges. For example, sub nanometer level roughness around a waveguide surface made with silicon creates a higher optical loss compared to the same roughness made in lower contrast materials like silicon nitride or glass. Also, the sizes of elements are small; therefore the fabrication tolerances compared to device sizes is more pronounced.

Imprecision in a device's dimensions results in changes to its optical functionalities. For example, small changes in a waveguide width or thickness changes its effective index. More particularly, light propagating along a waveguide having imprecisions acquires a different phase compared to that expected from an ideal waveguide. Such a deviation may change the overall circuit performance depending on the design. Another class of devices in which device imprecisions result in notable changes in functionality are optical cavity devices e.g., ring or photonic crystal resonators. The resonant frequency of such devices made with silicon are typically a very strong function of device dimensions. The fabrication tolerances, therefore, can impose a large scattering in expected resonances for such devices. The scattering in performance may yield, for example, an integrated optical filter misaligned with its target design wavelength.

A part of the deviation of device performance from design arises from systematic error and is arguably controllable and reproducible. For example, waveguides may turn out systematically a few nm wider than designed after going through a particular fabrication process. Such reproducible errors can be corrected by calibration runs of chip fabrication where the performance deviation is measured followed by applying a correcting bias to the layout before fabrication of further chips. The reproducible performance correction may be as simple as applying a constant bias to all devices, or it can be as complex as applying trained computational algorithms to compute the required correction given parameters like device type, neighboring devices, etc.

A second part of the deviation of device performance from design is statistical in nature. For example, two identically designed cavities sitting next to each other on a same chip may have slightly different resonance frequencies. Similarly, two chips manufactured using the same process and parameters may turn out to exhibit different properties. Unlike reproducible deviations that are introduced due to systematic errors, statistical variations cannot be predicted on an individual basis, hence cannot be corrected by layout preparation strategies such as calibration runs, and/or computational corrections.

One way to reduce the statistical deviations is to improve fabrication tolerances and/or generate device designs that are inherently less sensitive to device dimensions. Yet, in practice, the fabrication process cannot be pushed to the ideal limit, and device designs are not infinitely flexible. As a result, despite the precision of modern electronic fabrication methods, integrated photonic devices still suffer from statistical variations.

Another approach to correct for the statistical variations relates to building active control elements on the chip to actively compensate for device performance deviation in a fully fabricated device. For instance, a heater may be patterned next to a resonance cavity to dissipate electrical power to thereby change the cavity temperature. This has the effect of changing the refractive index of the materials, which enables tuning the cavity to a desired resonance. While this approach fulfils the need of tuning a desired parameter, such active approaches typically require additional on-chip real-estate, which are not easy to implement. Also, this approach may dissipate significant power, and typically requires additional control electronics.

Yet another approach for correcting statistical variations is to apply an interim trimming after an initial fabrication. In this approach, the optical performances of the fabricated devices are measured and fed into a further fabrication step, with the goal of applying fine changes to the devices. This approach generally requires that the magnitude of the change be individually tailored to the correction needed by each of the devices. There are a few propositions on how to accomplish this.

The first proposition involves relatively standard processes, which entails adding one or more material layers, such as silicon dioxide, silicon nitride, halfnium oxide, etc to the fabricated silicon chips. This is then followed by selective trimming i.e., removal of the added material using, for example, a lithography process followed by an etching process. These processes are not trivial for some devices including photonic crystal structures, especially considering that the added layer of material may not be compatible with the high aspect ratio of small crystal holes that may be present in such devices. Similarly, this approach requires that the alignment employed during the trimming lithography step be carefully matched to the devices that are pre-existing on the chip.

A second proposition involves non-standard processes that impose changes into cladding or buried oxide materials. This includes exposing a chromophore doped polymer cladding to a controlled electron beam, exposing buried oxide to strain silicon to trim the device, or annealing a spin-on glass resist on the device with a focused laser, which sometimes reaches temperatures as high as 1200° C. These processes are not easily controllable and may create changes that are potentially unstable or possibly damaging to some photonic devices. Also, these processes, being non-standard, can be slow, impractical for large scale fabrication, and usually require non-standard equipment.

A third proposition involves processes that impose changes in the silicon material structure itself. These changes include oxidation followed by removal of the oxide by wet etchants, and/or surface oxidation of silicon by heating due to prolonged exposure to a focused laser. These processes are not smooth and controllable. Also, they have been shown to exhibit relatively large minimum step size in trimming per each cycle and cannot easily be applied differently to individual devices on a single chip. Lastly, this proposition involves processes that are not as accurate as some of the relatively standard processes.

As will be appreciated, a method of trimming photonic chips comprising one or more devices (e.g., on-chip devices) that can be performed without adding further materials is desirable. The method should be easy and fast to perform. The method should be implementable in trimming devices with high aspect ratios or devices having small structures.

In the following description, embodiments of systems and methods of trimming a photonic chip are described.

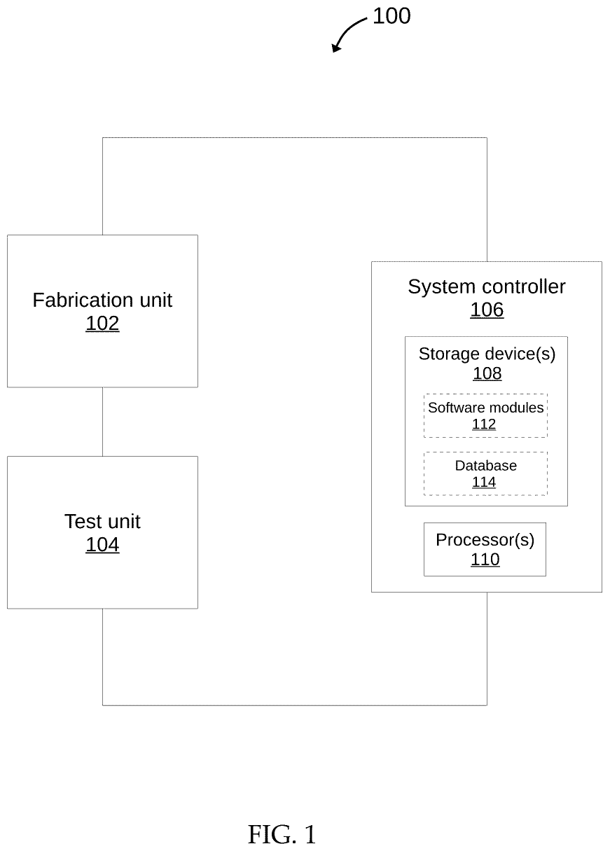

Turning now to FIG. 1, a block diagram of a system for manufacturing a photonic chip is shown and is generally identified by reference numeral 100. In this embodiment, the photonic chip manufacturing system 100 is suitable for manufacturing a photonic chip having a plurality of components (devices) integrated thereon/therein. Examples of these devices are optical cavities, resonant channel drop filters, waveguides, coupled ring resonators, etc. As can be seen, system 100 includes a fabrication unit 102, a test unit 104, and a system controller 106.

The fabrication unit 102 fabricates a photonic chip using a combination of fabrication processes, including material deposition, pattern defining, and pattern transfer. During material deposition, materials are deposited on the handling wafer (Si wafer or SOI wafer or similar wafer) using one or more deposition techniques. For example, the materials may be deposited using Chemical Vapor Deposition (CVD), Molecular Beam Epitaxy (MBE), sputtering, or any other conventional deposition technique. The pattern defining process may be performed, for example, using lithography techniques (for example optical lithography, electron-beam lithography, etc.). The pattern transfer process may include, for example, applying one or more etching techniques to the photonic chip. After pattern transfer, the photonic chip may undergo additional material deposition using any one of the deposition techniques mentioned previously. Depending on the type and function of the photonic chip, the fabrication process may involve additional steps, for example ion implantation, annealing, layer transfer, etc. One or more fabrication processes may be repeated, in no particular order, depending on the complexity of the photonic chip to be fabricated.

The test unit 104 measures the optical performance of the fabricated photonic chip using one or more testing equipment. Examples of testing equipment include optical probe stations and spectrometers. The testing may be performed while performing one or more fabrication processes (in-situ) or after all the fabrication processes have been completed (ex-situ). The testing may include measuring a value of a performance metric of interest for one or more devices on the photonic chip against a predefined value of the performance metric. The performance metric of interest may, for example, be any one of energy, frequency, wavelength, phase, or Q-factor of one or more devices on the photonic chip.

The controller 106 is communicatively coupled to the fabrication unit 102 and test unit 104. Controller 106 includes one or more storage devices 108 and one or more processors 110 communicatively coupled to the one or more storage devices 108. The storage device 108 can be a hard disk or other tangible, non-transitory computer readable medium. The storage device 108 stores one or more software modules 112 that are executed by one or more processors 110. The storage device 108 further stores a database 114 containing one or more record of data that are utilized in conjunction with the software modules 112 by the processor 110. The data may include training data comprising fabrication process simulation data, fabrication process characterization data, in-process inspection data, post-build inspection data, or any combination thereof, used by the processor to optimize one or more parameters used during fabrication.

By executing one or more software modules 112, the processor 110 causes the controller 106 to perform a variety of functions within the photonic chip manufacturing system 100. For example, the processor 110 may execute a (CAD) software module 112 that causes the controller 106 to generate one or more photonic chip designs to be fabricated by the fabrication unit 102. Similarly, the processor 110 may execute an optimization routine that causes the controller 106 to optimize one or more process parameters during fabrication. The process parameters include plasma chamber control settings which, depending on the type of plasma chamber used, may include RF power and chamber pressure.

In another embodiment, rather than software modules 112 executed by the processor 110, hardware modules (not shown) may be implemented. The hardware modules may be internal or external to the controller 106. Combinations of software and hardware modules may also be utilized in other embodiments.

In some embodiments, rather than having a controller 106 that provides commands and instructions to the fabrication unit 102 and test unit 104, each individual unit may include a local controller that controls the operations of the respective unit. For example, a first local controller associated with the fabrication unit 102 may control the fabrication process, while a second local controller associated with the test unit 104 may control the tests to be carried out on the photonic chip. The first controller may be configured to communicate with the second controller. Other embodiments may include controller 106 and one or more local controllers.

Further details of how the controller 106 operates in various exemplary embodiments are provided in the following.

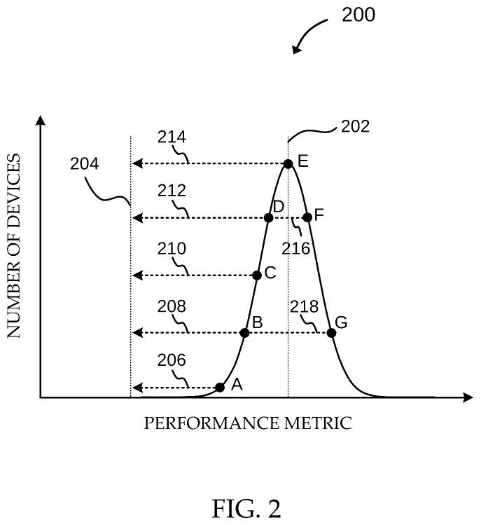

Turning now to FIG. 2, a statistical distribution of devices on a photonic chip according to a performance metric is shown and is generally identified by reference numeral 200. The performance metric of interest generally depends on the type of device. For example, a performance metric of interest for optical cavity devices may be the cavity resonance wavelength or resonance frequency.

As described previously, owing to systematic and statistical variations that are inadvertently introduced during fabrication, a photonic chip may end up in a state where its optical performance is upstream (exceeds) or downstream (falls short) of its intended optimal optical performance. FIG. 2 illustrates a scenario where a photonic chip is initially in an offset state 202 that is upstream of an optimal state 204. As used here, the term optimal state 204 refers to a state in which a value of the performance metric for each device on the photonic chip is optimum, while the term offset state 202 refers to a state in which the value of the performance metric for each device exceeds that in the optimal state 204. Similarly, a device is said to be in the offset state if the value of its performance metric in said state is different from the value of its performance metric in the optimal state.

As can be seen, in the offset state 202, the performance metric distribution of the devices on the photonic chip is described by a bell curve. The devices are classified into bins A, B, C, D, E, F, or G based on their performance metric. Each bin A, B, C, D, E, F, or G is associated with a respective performance deviation 206, 208, 210, 212, 214, 216, and 218, that defines an amount of trimming that needs to be applied to bring a device to the optimal state 204. In other words, the performance deviation 206, 208, 210, 212, 214, 216, and 218 is used in calculating one or more parameters to be applied when performing the trimming method described below.

As will be appreciated, one or more additional offset states may exist between the offset state 202 and the optimal state 204. In such embodiments, the trimming method may be applied in a stepwise manner having multiple trimming cycles such that each trimming iteration brings the device closer to the optimal state 204. One or more of these offset states may be prepopulated or dynamically generated based on the particulars of the photonic chip. A table of offset states may be stored in the database 114 of the controller 106.

Although shown here as having a common optimal state 204, each one of bins A, B, C, D, E, F, and G may have an associated optimal state that is unique to each bin. This may or may not translate to each bin having a different performance deviation. As will be appreciated, the trimming method described below is independent of whether the devices on the photonic chip have a common optimal state (as illustrated in FIG. 2) or different optimal states. Similarly, although defined as being upstream of the optimal state 204, the offset state 202 may be downstream of the optimal state 204, such that the value of the performance metric for each device in the offset state 202 is less than the value in the optimal state 204.

The method of trimming a photonic chip described below applies to photonic chips that are fabricated in the offset state. The photonic chip may be fabricated deliberately in the offset state or due to inadvertence, as previously described. The method of trimming a photonic chip disclosed herein uses resist patterns created on the photonic chip in trimming the photonic chip. In some embodiments, trimming the photonic chip includes exposing the chip to a plasma of reactive gas to selectively and controllably convert portions of the core of a device on the photonic chip into a different material, which may or may not be removed after final fabrication. The conversion of the portion of the core into the different material constitutes a change in the structure of the device which in turn changes its optical functionality and/or performance. Using resist patterns to selectively expose certain portions of the core of the device to a controlled plasma process allows for the performance of the device to be finely tuned, over one or more trimming iterations, toward the optimal state.

It should be noted, that depending upon the device, the optimal state may fall within an expected distribution—and depending upon the particulars of the patterned resists and process parameters applied, trimming using a plasma of reactive gas to shift the value of the performance metric of that device in a desired direction may be advantageous. Although only one performance metric has been indicated in FIG. 2, the devices may deviate over multiple performance metrics. Any number of these may be used as the basis for trimming the device towards target functionality. It also should be understood that multiple devices on a single photonic chip/wafer may each have a different optimal state and may or may not be designed with initial targets which takes into account the final differences. In some embodiments, different devices with different optimal states undergo the same initial fabrication process but are each individually trimmed in different ways as necessary.

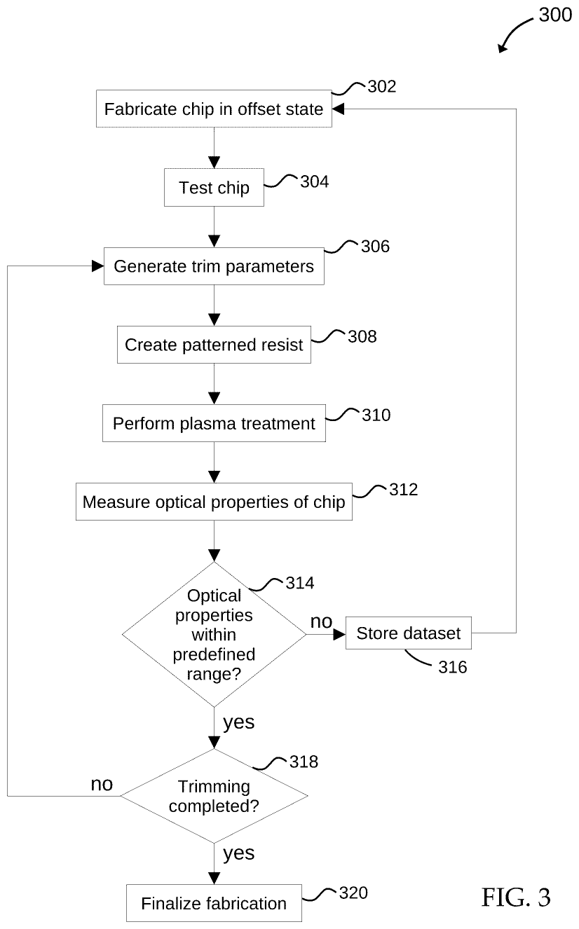

Turning now to FIG. 3, a flowchart describing a method of trimming a photonic chip is shown and is generally identified by reference numeral 300. The steps of the flowchart are not restricted to the exact order shown, and, in other embodiments, shown steps may be omitted or other intermediate steps added. In this embodiment, the processor 110 executes one or more software modules 112 in order to cause the controller 106 to perform the illustrated steps.

As can be seen, the process begins at step 302 where a photonic chip (e.g., one or more photonic devices of the chip) is fabricated in an offset state, for example the offset state 202 described in FIG. 2. In the offset state, the performance metric of one or more devices on the photonic chip has a value that is greater than or less than a predefined/desired optimal value. In some embodiments, the photonic chip is fabricated deliberately in the offset state. This may be achieved by tuning one or more parameters during the design and/or fabrication to cause the photonic chip to be in the offset state. For example, a bias can be applied to certain geometrical dimensions.

At step 304, the controller initiates chip testing. The testing may include examining a physical structure of the photonic chip under a microscope and/or measuring the optical performance of the photonic chip. Testing may further include testing one or more devices on the photonic chip to determine a performance deviation for the devices. The performance deviation is determined through optical characterization of the devices. The type of test performed generally depends on the type of device and the performance metric of interest. For example, a device may be measured for its optical functionality according to one or more performance metrics. In some embodiments, the device is substantially complete, for example, requiring no additional materials or cladding to finalize fabrication. In such embodiments, the testing 304 is performed by measuring the device. In other embodiments, the device is incomplete, requiring additional materials or cladding to reach its final form. In these embodiments, testing may include first, temporarily coating the device to simulate the performance the device is expected to have in its final form, followed by measuring the device. This temporary coating may include adding a temporary material to the device, which is later removed. The temporary material may possess optical properties that are similar to a permanent material that is anticipated (e.g., in a later step) to be added to the device. For example, in a case where additional cladding is planned, the temporary material may have an index of refraction matching the index of refraction of the material to be added during additional cladding. The structure and dimensions of the temporary material may be about the same as the material to be added during additional cladding. In some embodiments, this involves spin-coating the index matching material (a resist or similar material) on the device and baking the photonic chip to remove solvents in the spin-coating material prior to taking measurements. It should be noted that materials like resists or index matching liquids are better suited for use as the temporary material compared to harder options like silicon dioxide which is less easy to remove. After testing 304 is complete. The temporary materials may be removed, for example, with appropriate solvents, before proceeding to other steps.

At step 306, results (e.g., the optical performance of the device) from the tests performed at step 304 are used in identifying the type and/or magnitude of the performance deviations and in determining trim patterns and process parameters. This is achieved by feeding the results as input to an algorithm and/or through information contained in a lookup table. The performance deviation is used in determining the trim direction, and the amount of trimming required to bring a device to its optimal state. Trimming is controlled to correct the device fully or to move the device performance toward the optimal state, such as in iterative embodiments discussed below. Determining the trim pattern may further include determining the size, shape, and position of one or more areas on each of the devices for which the trim pattern may be employed to mask the trimming in a controlled manner. The resulting trim pattern is exported as a design layer similar to the other design layers commonly used in photonic chip design. Similarly, determining the process parameters may include a determination of a reactive gas that is suitable for the trimming and/or one or more process parameters for treating the device with a plasma of the reactive gas. The process parameters are stored or provided to ensure the correct operation of the equipment used in performing the plasma treatment process.

In some embodiments, the process parameters are not determined at step 306 but are predetermined. In such a case, the parameters constitute fixed conditions that the algorithm may use in determining the size and position of the opening in the trim pattern resist which will result in the desired correction. In other embodiments, in addition to the process parameters, specific constraints on the resist pattern are also predetermined. An example would be a preset opening constrained by a fixed length but with a width which can be varied according to performance. In such embodiments, only a finite number of controlling variables (e.g., a width of an opening) are varied and optimized by the algorithm.

As will be appreciated, some devices may require multiple trimming iterations to correct a performance deviation. In these embodiments, the controller determines, based on the performance iteration, the number of trimming iterations, as well as a performance tolerance for each iteration, required to correct the performance deviation. For example, the controller may determine that three trimming iterations are required to correct the performance deviation of a particular device and further generate performance tolerance for each one of the three trimming iterations. The first trimming iteration (e.g., a global trim that may act on one or more devices including the particular device) may be a coarse iteration, hence have the largest performance tolerance, while the third trimming iteration (e.g., a local trim that only affects the particular device), being the finest iteration, may have the least performance tolerance. In some embodiments, each subsequent trimming iteration has a smaller performance tolerance than a preceding trimming iteration.

At step 308, a resist pattern is created using the determined trim patterns from step 306. The resist pattern is created by coating the photonic chip with a photo-resist or electron-resist, and a lithography tool is used to expose the trim pattern. The resist is then developed, yielding openings in the trim patterned resist. In some embodiments, creating the resist pattern is sufficient to adjust the performance metric of interest to the predefined optimal value. In some embodiments, additional steps (e.g., optional step 310) are performed to further trim the photonic chip.

At optional step 310, the photonic chip is exposed to a plasma of reactive gas such as oxygen plasma and/or nitrogen plasma in order to convert at least a portion of a core material of the device exposed by the openings in the resist while the resist blocks conversion elsewhere. In some embodiments the plasma is a plasma of a reactive gas (e.g., oxygen or nitrogen) mixed with a non-reactive gas (e.g., an inert gas such as argon).

For example, the plasma may be a plasma of a mixture comprising 15-50% oxygen by mass and 50-85% argon by mass. Including a non-reactive gas in the plasma can advantageously cause the plasma to erode the mask (patterned resist) less while converting the exposed core material to a given depth. For example, a plasma mixture comprising 15-50% oxygen and 50-85% argon provides up to 40% improvement in selectivity for converting the core material vs. mask erosion than a pure oxygen plasma. The increased selectivity achievable with a plasma based on a mixed gas can enable use of thinner masks and/or application of plasma for longer times and/or at higher plasma energies with a given thickness of mask. A mass fraction of argon toward the higher end of the 50-85% range has been found to provide good results while allowing a stable plasma to be maintained in proof of principle experiments.

The selectivity of a plasma based on a particular gas mixture for converting the core material vs. mask erosion may be measured, for example, by exposing two samples, one covered with a resist and another bare silicon to the plasma for a given time and measuring thickness of the resist and thickness of the silicon before and after exposure of the samples to the plasma. A ratio of the reduction of thickness of the silicon to the reduction in thickness of the resist caused by the exposure may be used as a measure of selectivity.

Although the inventors do not wish to be bound by any particular theory of operation it is thought that ions of the non-reactive gas physically disrupt oxide that tends to form on the exposed core material during the process, thereby extending the depth to which the core material can be converted before any saturation takes place and also potentially decreasing the time required to convert the core material to a given depth. Furthermore, inclusion of the non-reactive gas reduces the concentration of oxygen ions in the plasma which may reduce the rate at which mask material is etched (particularly where the material of the mask is sensitive to oxygen—e.g. soft polymer mask material). In some embodiments masks are made with soft polymer mask material.

The process is performed using the process parameters determined at step 306 (or the predetermined parameters if applicable) for applying the requisite magnitude of trimming to the device i.e., for converting the exposed core material to the different material to the desired thickness or depth. This adjusts the shape and/or size of the core material structures exposed in the openings in the resist to the plasma by transforming the core material which defines the device into the different material which defines its immediate surroundings. This different material may or may not match any additional material or subsequent cladding material added in further fabrication steps.

The depth of the plasma treatment process trimming is determined globally by the plasma parameters (e.g., RF power, chamber pressure, exposure time) used in accordance with the designed process parameters. A lower depth level can therefore be used for a finer trim process, and a higher depth level can be used for a rougher trim step. The magnitude of the effect of the trimming is also determined locally by the design of the resist openings.

Generally, the accuracy of trimming depends on the accuracy (controllability) of the oxidation or nitridation depth, the accuracy of defining openings in the resist, as well as the accuracy of the alignment of the resist openings with original structures on the wafer. Although setting the process for a smaller oxidation or nitridation depth cannot change the magnitude of the resist lithography errors, it does make a smaller trimming range. Therefore, the smaller the oxidation or nitridation depth, the smaller the trim range, and the higher the trim accuracy. This can be used to design iterative trim steps to increase final accuracy of the devices.

At step 312, one or more optical properties of the photonic chip is measured. Step 312 may include, for example, measuring the performance of individual devices on the photonic chip. The photonic chip may be optionally temporarily coated and tested. The temporary coating may be removed after testing, in a substantially similar fashion to that of step 304.

At step 314, the controller determines whether the measured optical properties are within a predefined range and/or meet acceptability criteria/standards. This includes determining whether the performance metric of one or more devices on the chip is within a predefined performance tolerance. In some embodiments, the acceptability criteria are used to determine whether the photonic chip is acceptable in terms of absolute performance. In such cases, the acceptability criteria may further include a number of trimming iterations to be performed on the photonic chip and/or how much each device on the photonic chip has improved in performance since the previous iteration or in comparison to a predetermined expected or desired amount, etc. If the device is determined to be acceptable, control proceeds to step 320, otherwise control proceeds to step 316 to store the dataset.

At step 316, the controller stores the dataset from the measurement of the photonic chip having determined that one or more optical properties is outside of the predefined range. The stored dataset may be used to optimize one or more fabrication processes and/or subsequent trimming operations.

At step 320, the controller determines whether trimming is completed. Trimming is complete when the number of trimming iterations generated by the controller have been completed. If there are trimming iterations yet to be completed, control returns to step 308 to generate patterned resist for the next trimming iteration. Each trimming iteration may be more precise than a preceding trimming iteration. For example, a first trimming iteration may be coarse while subsequent iterations may be more precise. This is achieved by varying the process parameters (including the type of reactive gas), the shape and/or size of the openings in the resist, or both during each trimming iteration.

At step 322, the controller finalizes the fabrication. This may include the removal of resists and/or application of a cladding.

It should be noted that typical commercially available plasma chambers are capable of performing the required plasma treatment process without requiring any modifications. These chambers are typically used for common applications such as: descum, ash, etch, clean, and surface activation/treatment. It also should be understood that the reactive gases which can be advantageously used in the plasma treatment process depend upon the core and surrounding materials in the device and the associated chemistry. For example, in the commonplace context of devices utilizing silicon as the core material, oxygen may be used for the plasma treatment. In such a case, conversion comprises oxidation of the silicon producing silicon dioxide. It should be noted that both oxygen and nitrogen are typical reactive gases used for plasma in typical plasma chambers, and both can be used for trimming silicon core devices on a SOI platform.

It should be noted that oxidation of silicon according to an oxygen plasma treatment process is a self-terminating process which means that as the oxide grows under oxygen plasma, the presence of oxide on the surface functions as a barrier for the plasma to reach further silicon, thereby inhibiting further oxidation. As a consequence, the curve of oxidation amount versus oxidation time tends to saturate and varies similar to a logarithmic curve. This means that for sufficiently long plasma exposure the ultimate amount of silicon oxidized does not sensitively depend on the initial plasma conditions. Self-termination also makes the oxidation rate particularly slow (e.g., <0.03 nm per second) after sufficiently long exposure (e.g., >30 sec), so the amount of silicon oxidized does not sensitively depend on the length of time during which the plasma is applied. Another advantage the self-termination offers is the uniformity of oxidation depth over large wafer surfaces. Yet another advantage of self-termination is the negligible extra roughness oxidation may induce on silicon. All of these properties help make plasma oxidation clean and controllable with sub nm precision. Such level of reproducibility and precession is not typically offered by plasma etching methods in which etch byproducts are volatile gasses and no self-termination happens. Like plasma oxidation, plasma nitridation offers similar advantages.

It should be noted that oxygen plasma is widely used in nanofabrication to descum organic materials and residues. As noted above, oxidation of silicon with plasma is a self-terminating process, therefore, descums typically do not oxidize the silicon deeper than 1-2 nm. This self-terminating oxidation of silicon is ideal for descums since they are intended only to remove unwanted material residue (such as residual photoresist) from a silicon wafer. Descums are not meant to actively convert the silicon material to any appreciable degree let alone by an amount which changes the structure or function of a silicon core device. It should be noted that the typical depth of 1-2 nm of silicon dioxide a descum process typically produces is not high enough for practical use in the trimming method.

In contrast with typical descum processes, the present method utilizes a plasma treatment process which has a pressure in the plasma chamber below what is commonly used in a descum. This lower pressure together with an increase in RF power applied to the chamber can increase the ion acceleration toward the silicon, which can advantageously increase the oxidation depth to a level beyond what is normally expected or desired from a descum process. The 1-2 nm achievable by a descum process is typically not high enough to achieve the much deeper desired trimming depth which might, for example, be as deep as 10 nm.

Oxygen and/or nitrogen plasma is also used in dry etching applications; however, dry etching processes typically include corrosive plasma etching agents such as fluorine, or chlorine. These processes are intended for removal of material rather than conversion and retention of material. Consequently, such dry etching approaches are not self-terminating and are generally not controllable or reproducible to the precision a trimming process demands.

The present plasma oxidation or nitridation process offers two major advantages over the use of “dry etching” of silicon. The first advantage is that the oxidation or nitridation depth is highly reproducible down to around 0.1-0.3 nm accuracy. In comparison, the depth resulting from dry etching is not considered reproducible. A successful trimming is in need of this reproducibility, otherwise the devices will experience a trimming different from the expected/calculated value. The second advantage is that plasma oxidation or nitridation does not increase or may even decrease the surface roughness of the silicon devices. In contrast, dry etching can substantially increase the surface roughness. Increased roughness scatters guided light and may severely degrade the optical performance.

Additional benefits of the method trimming a photonic chip described above will now be discussed.

Accordingly, the method can be applied to silicon photonic chips with precision using existing machinery. This is unlike other trimming processes that require non-standard equipment.

Second, the lithography step of creating the patterned resist can be executed using fast direct writers, and the plasma treatment process can be applied to the whole wafer. In other words, the plasma treatment process may be applied to all devices on a wafer simultaneously. As such, the method of trimming a photonic chip described herein maintains a high throughput compared to known processes.

Third, the plasma application at higher ion acceleration (higher RF power and/or lower chamber pressure) is a directional process. That means the top surface is oxidized deeper than any vertically etched silicon walls which are typically made by dry etching processes. This directionality is not present in some of the reviewed processes discussed above. The directionality of the method of trimming disclosed herein helps to simplify the algorithm that computes the trim parameters and also helps achieve the required precision.

Fourth, the method can be tuned for accuracy, depending on details of device and process design. Trimming accuracy depends primarily on two factors, the accuracy of the openings in the resists (shape and placement), and the accuracy with which the trimming saturation may be controlled. Standard lithography provides accuracy on openings definition, i.e., where the silicon is treated, and the accuracy of the plasma oxidation or nitridation process provides accuracy in the depth of silicon conversion.

Fifth, the method may be carried out at relatively low temperatures reducing any likelihood of damage to the devices on the photonic chip. The highest temperature the devices receive during the trimming operation is much smaller than of a resist backing step, which is typically equal to or less than approximately 180° C., not routinely considered as a high temperature in chip manufacturing.

Sixth, the method does not cause strain on the device silicon layer, nor does it add extra material layers to the photonic chips. Therefore, there is nothing extra on the devices to cause strain changes.

Seventh, the method can be used to provide different trimming to different devices that share a photonic chip and/or wafer. Devices which require different trimmings each can have their own unique openings in the resist.

Eighth, the method does not result in additional photonic losses caused by absorption or scattering from deposited materials such as used in other known processes. The method does not add materials to the devices, instead converting them, so there is no additional absorption or scattering because of the presence of more materials the optical field interacts with. Furthermore, the plasma treatment process described herein maintains the original device surface roughness and/or reduces the roughness, as such, it does not increase scattering losses. While the interface between oxidized and non-oxidized (or nitridated and non-nitridated) surfaces may cause additional scattering, this contribution is accounted for when generating the trim patterns and/or when designing the photonic chip.

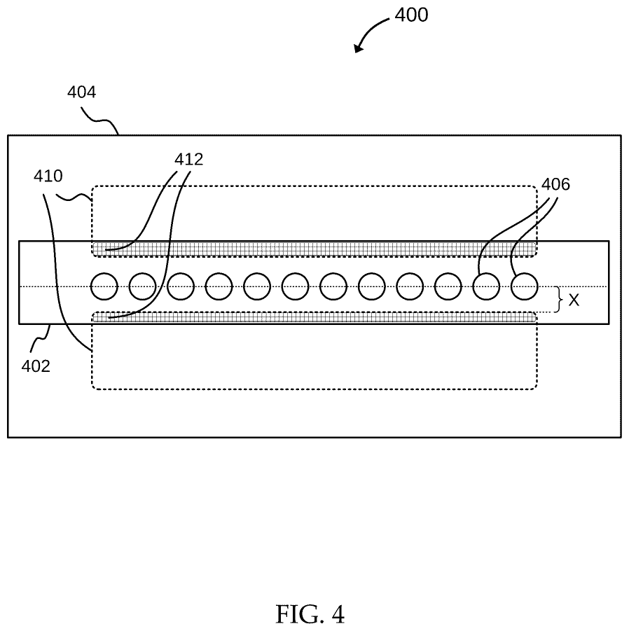

Referring to FIG. 4, an example application of the method of trimming a photonic device as disclosed herein will now be discussed. In this embodiment, the photonic device is a nanobeam cavity device 400. The nanobeam cavity device 400 comprises a silicon structure 402 having a plurality of holes 406 etched thereon. The silicon structure 402 is surrounded by a silicon dioxide material 404. Resist openings 410 in a trim pattern resist exposes areas of overlap 412 between the trim pattern and the edges of the silicon structure 402. The area of overlap 412 scales inversely as a parameter X, defined as the distance between the edge of the resist opening 410 and a horizontal bisector of the holes 406 etched in the silicon structure 402.

In this example, the nanobeam cavity device 400 is tuned to exhibit a desired resonance by converting a part of the silicon structure 402 into silicon dioxide. This is achieved by subjecting the area of overlap 412 to the plasma treatment process described FIG. 3, using oxygen plasma as the reactive gas. The plasma treatment process results in depletion of the silicon structure 402 edges as a portion of the silicon structure 402 is converted into silicon oxide by oxidation, which in turn results in a change in the resonance wavelength of the nanobeam cavity device.

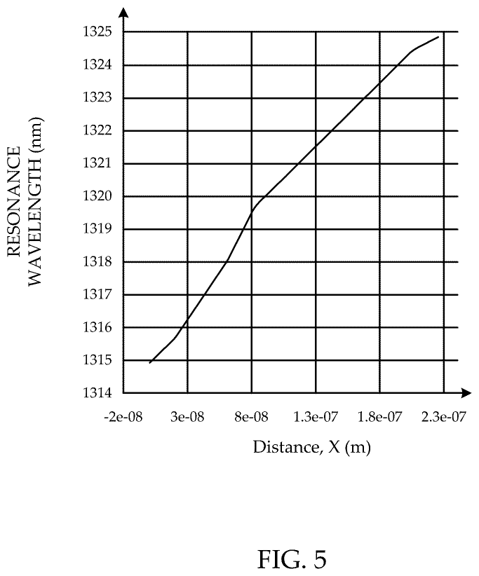

A simulated trimming curve of the resonance wavelength of the nanobeam cavity device 400 as a function of the parameter X is shown in FIG. 5. As can be seen, the resonance wavelength increases with X as portions of the silicon structure 402 becomes converted into silicon oxide. The marked change in slope of the graph at X=8E-08 m occurs when the plasma treatment process reaches the perimeter of the holes 406 etched in the silicon structure 402.

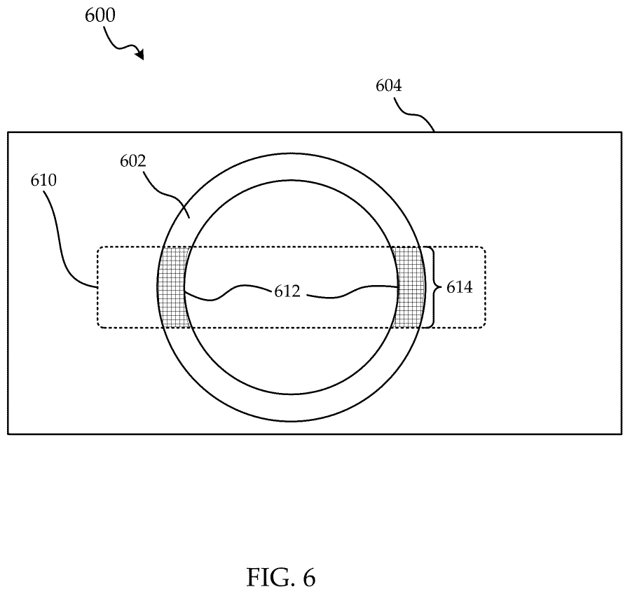

Referring to FIG. 6, another example application of the method of trimming a photonic device as disclosed herein will now be discussed. In this embodiment, the photonic device is a micro-ring device 600. The micro-ring device 600 includes a ring silicon structure 602 surrounded by a silicon dioxide material 604. The method of trimming of FIG. 4 is applied to tune the micro-ring device 600 to exhibit a desired resonance. Resist opening 610 in the trim pattern resist exposes areas of overlap 612 between the trim pattern and portions of the silicon ring structure 602. As the silicon within the overlap is subject to the plasma treatment described herein, a portion of the silicon is converted into a different material. For example, when the plasma treatment is performed using oxygen as the reactive gas, the portion of the silicon structure 602 within the overlap oxidizes to silicon dioxide, thus effectively trimming the dimensions of the silicon structure 602. In this example, a depth of two segments of the silicon ring structure 602 sides is effectively reduced. The magnitude of the trimming and the resonance wavelength shift varies with the plasma exposure parameters, and the amount of the overlap 612 which depends on the width 614 of the resist opening 610.

Although specific examples of the above plasma treatment process have been described in the context of oxygen plasma applied to silicon to create silicon dioxide, other types of reactive gases may be utilized as plasma during trimming and are contemplated as falling within the general method described hereinabove. For example, other plasma processes might include, but are not limited to, nitrogen plasma processing. The above disclosed methods and teachings are equally valid for a nitrogen plasma, but instead of oxidation, nitridation occurs. As noted above, nitrogen is a commonly available gas in plasma chambers. An advantage of nitrogen plasma over oxygen plasma is that it does not etch the masking resists as quickly as oxygen plasma does. Therefore, a thinner resist can be used, the thinner the resist, the smaller the minimum feature size of the trimming windows.

It should be noted that a silicon-SiO₂ interface is cleaner than Si-Silicon Nitride interface and could be important for some devices, and with nitride, the exact composition of the nitride layer would be ambiguous. Device design and requirements should be taken into account as factors for the choice of plasma used for the plasma processing in accordance with the above, whether an oxygen, nitrogen, or some other plasma is utilized.

Although specific examples of the above systems and methods of trimming have been described in the context of SOI-based photonic chips, it should be understood that plasma treatment processing according to the above systems and methods is contemplated for other photonic platforms including silicon nitride, and others. The plasma treatment process, in general, transforms the primary optical signal guiding or core material of the photonic device into a different material which remains in the photonic device, i.e. is not removed during plasma treatment. The different material is often similar to and in some embodiments is the same as a cladding material surrounding the core material in the photonic device after fabrication. In general, the approach trims the photonic device by tuning the dimensions of the core material.

A controller for all of part of a system as described herein may be implemented in any of a wide variety of ways which may include specifically designed hardware, configurable hardware, programmable data processors configured by the provision of software (which may optionally comprise “firmware”) capable of executing on the data processors, special purpose computers or data processors that are specifically programmed, configured, or constructed to perform one or more steps in a method as explained in detail herein and/or combinations of two or more of these. Examples of specifically designed hardware are: logic circuits, application-specific integrated circuits (“ASICs”), large scale integrated circuits (“LSIs”), very large scale integrated circuits (“VLSIs”), and the like. Examples of configurable hardware are: one or more programmable logic devices such as programmable array logic (“PALs”), programmable logic arrays (“PLAs”), and field programmable gate arrays (“FPGAs”). Examples of programmable data processors are: microprocessors, digital signal processors (“DSPs”), embedded processors, graphics processors, math co-processors, general purpose computers, process controllers, server computers, cloud computers, mainframe computers, computer workstations, and the like. For example, one or more data processors in a control circuit for a system or component of a system as described herein may implement methods as described herein by executing software instructions in a program memory accessible to the processors.

A controller may include plural components which may be at a common location or distributed.

Some aspects of the present technology are provided in the form of a program product. The program product may comprise any non-transitory medium which carries a set of computer-readable instructions which, when executed by a data processor, cause the data processor to execute a method of the invention. Program products according to the invention may be in any of a wide variety of forms. The program product may comprise, for example, non-transitory media such as magnetic data storage media including floppy diskettes, hard disk drives, optical data storage media including CD ROMs, DVDs, electronic data storage media including ROMs, flash RAM, EPROMs, hardwired or preprogrammed chips (e.g., EEPROM semiconductor chips), nanotechnology memory, or the like. The computer-readable signals on the program product may optionally be compressed or encrypted.

In some embodiments, the invention may be implemented in software. For greater clarity, “software” includes any instructions executed on a processor, and may include (but is not limited to) firmware, resident software, microcode, code for configuring a configurable logic circuit, applications, apps, and the like. Both processing hardware and software may be centralized or distributed (or a combination thereof), in whole or in part, as known to those skilled in the art. For example, software and other modules may be accessible via local memory, via a network, via a browser or other application in a distributed computing context, or via other means suitable for the purposes described above.

While particular implementations and applications of the present disclosure have been illustrated and described, it is to be understood that the present disclosure is not limited to the precise construction and compositions disclosed herein and that various modifications, changes, and variations can be apparent from the foregoing descriptions without departing from the spirit and scope of an invention as defined in the appended claims.

Where a component (e.g. a software module, processor, assembly, device, circuit, etc.) is referred to herein, unless otherwise indicated, reference to that component (including a reference to a “means”) should be interpreted as including as equivalents of that component any component which performs the function of the described component (i.e., that is functionally equivalent), including components which are not structurally equivalent to the disclosed structure which performs the function in the illustrated exemplary embodiments of the invention.

### Interpretation of Terms

Unless the context clearly requires otherwise, throughout the description and the claims:
“comprise”, “comprising”, and the like are to be construed in an inclusive sense, as opposed to an exclusive or exhaustive sense; that is to say, in the sense of “including, but not limited to”;
“connected”, “coupled”, or any variant thereof, means any connection or coupling, either direct or indirect, between two or more elements; the coupling or connection between the elements can be physical, logical, or a combination thereof;
“herein”, “above”, “below”, and words of similar import, when used to describe this specification, shall refer to this specification as a whole, and not to any particular portions of this specification;
“or”, in reference to a list of two or more items, covers all of the following interpretations of the word: any of the items in the list, all of the items in the list, and any combination of the items in the list;
the singular forms “a”, “an”, and “the” also include the meaning of any appropriate plural forms. These terms (“a”, “an”, and “the”) mean one or more unless stated otherwise;
“and/or” is used to indicate one or both stated cases may occur, for example A and/or B includes both (A and B) and (A or B);
“approximately” when applied to a numerical value means the numerical value±10%;
where a feature is described as being “optional” or “optionally” present or described as being present “in some embodiments” it is intended that the present disclosure encompasses embodiments where that feature is present and other embodiments where that feature is not necessarily present and other embodiments where that feature is excluded. Further, where any combination of features is described in this application this statement is intended to serve as antecedent basis for the use of exclusive terminology such as “solely,” “only” and the like in relation to the combination of features as well as the use of “negative” limitation(s)” to exclude the presence of other features; and
“first” and “second” are used for descriptive purposes and cannot be understood as indicating or implying relative importance or indicating the number of indicated technical features.

Words that indicate directions such as “vertical”, “transverse”, “horizontal”, “upward”, “downward”, “forward”, “backward”, “inward”, “outward”, “left”, “right”, “front”, “back”, “top”, “bottom”, “below”, “above”, “under”, and the like, used in this description and any accompanying claims (where present), depend on the specific orientation of the apparatus described and illustrated. The subject matter described herein may assume various alternative orientations. Accordingly, these directional terms are not strictly defined and should not be interpreted narrowly.

Where a range for a value is stated, the stated range includes all sub-ranges of the range. It is intended that the statement of a range supports the value being at an endpoint of the range as well as at any intervening value to the tenth of the unit of the lower limit of the range, as well as any subrange or sets of sub ranges of the range unless the context clearly dictates otherwise or any portion(s) of the stated range is specifically excluded. Where the stated range includes one or both endpoints of the range, ranges excluding either or both of those included endpoints are also included in the invention.

Certain numerical values described herein are preceded by “about”. In this context, “about” provides literal support for the exact numerical value that it precedes, the exact numerical value±5%, as well as all other numerical values that are near to or approximately equal to that numerical value. Unless otherwise indicated a particular numerical value is included in “about” a specifically recited numerical value where the particular numerical value provides the substantial equivalent of the specifically recited numerical value in the context in which the specifically recited numerical value is presented. For example, a statement that something has the numerical value of “about 10” is to be interpreted as: the set of statements:
in some embodiments the numerical value is 10;
in some embodiments the numerical value is in the range of 9.5 to 10.5;
   and if from the context the person of ordinary skill in the art would understand that values within a certain range are substantially equivalent to 10 because the values with the range would be understood to provide substantially the same result as the value 10 then “about 10” also includes:
in some embodiments the numerical value is in the range of C to D where C and D are respectively lower and upper endpoints of the range that encompasses all of those values that provide a substantial equivalent to the value 10.

Specific examples of systems, methods and apparatus have been described herein for purposes of illustration. These are only examples. The technology provided herein can be applied to systems other than the example systems described above. Many alterations, modifications, additions, omissions, and permutations are possible within the practice of this invention. This invention includes variations on described embodiments that would be apparent to the skilled addressee, including variations obtained by: replacing features, elements and/or acts with equivalent features, elements and/or acts; mixing and matching of features, elements and/or acts from different embodiments; combining features, elements and/or acts from embodiments as described herein with features, elements and/or acts of other technology; and/or omitting combining features, elements and/or acts from described embodiments.

As will be apparent to those of skill in the art upon reading this disclosure, each of the individual embodiments described and illustrated herein has discrete components and features which may be readily separated from or combined with the features of any other described embodiment(s) without departing from the scope of the present invention.

Any aspects described herein in reference to apparatus may also apply to methods and vice versa.

Any recited method can be carried out in the order of events recited or in any other order which is logically possible. For example, while processes or blocks are presented in a given order, alternative examples may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, simultaneously or at different times.

Various features are described herein as being present in “some embodiments”. Such features are not mandatory and may not be present in all embodiments. Embodiments of the invention may include zero, any one or any combination of two or more of such features. All possible combinations of such features are contemplated by this disclosure even where such features are shown in different drawings and/or described in different sections or paragraphs. This is limited only to the extent that certain ones of such features are incompatible with other ones of such features in the sense that it would be impossible for a person of ordinary skill in the art to construct a practical embodiment that combines such incompatible features. Consequently, the description that “some embodiments” possess feature A and “some embodiments” possess feature B should be interpreted as an express indication that the inventors also contemplate embodiments which combine features A and B (unless the description states otherwise or features A and B are fundamentally incompatible).This is the case even if features A and B are illustrated in different drawings and/or mentioned in different paragraphs, sections or sentences.

It is therefore intended that the following appended claims and claims hereafter introduced are interpreted to include all such modifications, permutations, additions, omissions, and sub-combinations as may reasonably be inferred. The scope of the claims should not be limited by the preferred embodiments set forth in the examples, but should be given the broadest interpretation consistent with the description as a whole.

What is claimed is:

1. A method of trimming an integrated photonic device, the method comprising:
generating one or more trim patterns based on at least based on an optical measurement of the photonic device;
creating a patterned resist on the photonic device based on the one or more trim patterns; and
trimming the photonic device to adjust a performance metric of the photonic device.

2. The method according to claim 1, wherein the photonic device comprises a core and the trimming comprises converting a portion of the core from one material into another material.

3. The method according to claim 2, wherein the trimming comprises exposing the photonic device to a plasma of reactive gas.

4. The method according to claim 3, wherein the core is a silicon core.

5. The method of claim 3, wherein the trimming comprises converting the portion of the core into silicon nitride.

6. The method of claim 3, wherein the trimming comprises converting the portion of the core into silicon dioxide.

7. The method according to claim 1, wherein generating the one or more trim patterns is further based on a target optical performance for the photonic device.

8. The method according to claim 1 comprising fabricating the photonic device in an offset state in which a value of the performance metric in the offset state is different from a predefined optimal value of the performance metric in an optimal state, wherein the trimming causes the value of the performance metric to approach the predefined optimal value.

9. The method according to claim 1 comprising generating one or more process parameters based on the optical measurement and performing the trimming using the one or more process parameters.

10. The method according to claim 1, wherein the photonic device is one of a plurality of photonic devices fabricated on a common substrate, the method comprises performing the steps of the method for each of the plurality of photonic devices, and at least the step of trimming the photonic device to adjust the performance metric of the photonic device is performed simultaneously for the plurality of photonic devices.

11. A system for trimming one or more photonic devices of a photonic chip, the system comprising:
a fabrication unit; and
a system controller communicatively coupled to the fabrication unit, the system controller configured to:
cause the fabrication unit to fabricate the photonic chip such that the one or more photonic devices is in an offset state;
generate one or more trim patterns based on an optical performance of the one or more photonic devices and a first target optical performance for the one or more photonic devices of the photonic chip;
create a patterned resist on the photonic chip based on the one or more trim patterns; and
trim the one or more photonic devices of the photonic chip.

12. The system according to claim 11, wherein the first target optical performance is a predefined optimal optical performance of the one or more photonic devices in which a performance metric of the one or more photonic devices has a predefined optimal value.

13. The system according to claim 11, wherein the offset state is a state in which a value of the performance metric in the offset state is different from the predefined optimal value, wherein the trimming causes the value of the performance metric to approach the predefined optimal value.

14. The system according to claim 11 further comprising a test unit communicatively coupled to the fabrication unit and the system controller, wherein the test unit is configured to perform an optical characterization of the one or more photonic devices on the photonic chip to thereby determine the optical performance of the one or more photonic devices.

15. The system according to claim 11, wherein the system controller is configured to generate one or more process parameters based on optical measurements performed on the photonic chip and to control the trimming using the one or more process parameters.

16. The system according to claim 11, wherein the system controller is configured to determine the optical performance of the one or more photonic devices by optically measuring the one or more photonic devices using steps that comprise:
coating the one or more photonic devices with a temporary material to obtain one or more coated photonic devices;
optically measuring the one or more coated photonic devices; and
removing the temporary material prior to creating the patterned resist.

17. The system according to claim 16, wherein the temporary material has an index of refraction substantially the same as a material to be added to the one or more photonic devices in a later step.

18. The system according to claim 11, wherein the system controller is configured to iteratively repeat the steps of:
optically measuring the one or more photonic devices;
generating one or more trim patterns based on at least the optical measurements;
creating a patterned resist on the photonic chip based on the one or more trim patterns; and
trimming the one or more photonic devices to adjust a performance metric of the one or more photonic devices;
and thereby causing a value of the performance metric of the one or more photonic devices to progressively approach an optimum value for the performance metric of the one or more photonic devices.

19. A system for trimming one or more photonic devices of a photonic chip, the system comprising:
a system controller;
a measurement unit; and
a plasma chamber;
wherein the system controller is configured to:
acquire from the measurement unit optical measurements of optical characteristics of one or more photonic devices;
generate a respective trim pattern for the one or more photonic devices based on the optical measurements;
control a fabrication unit to create a patterned resist on the photonic chip based on the trim patterns; and
trim the one or more photonic devices by exposing the photonic chip to a plasma in the plasma chamber, the plasma comprising a reactive gas selected from oxygen and nitrogen.
